(19) United States
(12) Patent Application Publication
(10) Pub. No.: US 2010/0164019 A1
(43) Pub. Date: Jul. 1, 2010

(54) METHOD OF MANUFACTURING NONVOLATILE MEMORY DEVICE

(76) Inventor: Heedon Jeong, Gangnam-gu (KR)

Correspondence Address: SHERR & VAUGHN, PLLC, 620 HERNDON PARKWAY, SUITE 320, HERNDON, VA, 20170, US

(21) Appl. No.: 12/632,155

(22) Filed: Dec. 7, 2009

(30) Foreign Application Priority Data
Dec. 26, 2008 (KR) 10-2008-0134183

(51) Int. Cl. H01L 29/78; H01L 21/336

(52) U.S. Cl. 257/408; 438/286; 438/306; 257/E29.268; 257/E21.437

(57) ABSTRACT

A method of manufacturing a nonvolatile memory (NVM) device having a memory gate and a selection gate. A method of manufacturing a NVM device may include a spacer poly formed on and/or over a surface of a substrate including a memory gate. A method of manufacturing a NVM device may include a sacrificing film formed on and/or over a surface of a spacer poly. A method of manufacturing a NVM device may include an etch-back process performed to form a selection gate. The thickness of a memory gate may be minimized. A bridge between a selection gate and a source/drain may be minimized.

The present application claims priority under 35 U.S.C. 119 to Korean Patent Application No. 10-2008-0134183 (filed on Dec. 26, 2008) which is hereby incorporated by reference in its entirety.

### BACKGROUND

Embodiments relate to a method of manufacturing a memory device and devices thereof. Some embodiments relate to a method of manufacturing a nonvolatile memory (NVM) device which may include a memory gate and/or a selection gate.

A nonvolatile memory device may not loose stored data when power is shut off. A nonvolatile memory device may be used for computer bios and/or data storage in a settop box, a printer and/or a network server, for example. A nonvolatile memory device may be used in a digital camera, a mobile phone and/or a non-contact object recognition, for example, logistics by an RFID tag, entrance/exit management, accounting, and the like, which may use Radio Frequency Identification (RFID), and the like.

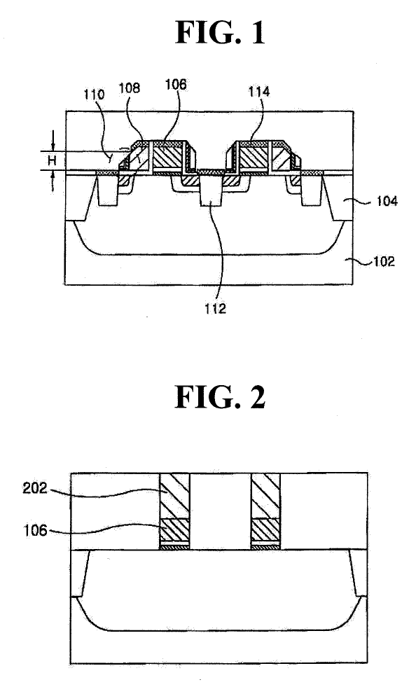

Referring to example FIG. 1, a sectional view illustrates a nonvolatile memory device. A nonvolatile memory device may include isolation film 104 formed on and/or over substrate 102, which may isolate devices from each other. Memory gate 106, selection gate 108, Lightly Doped Drain (LDD) spacer 110, source/drain region 112 and/or salicide 114 may be arbitrarily patterned. Deposition, masking, etching, cleansing, ion implantation, and the like, may be selectively performed to form, on and/or over substrate 102, device isolation film 104, memory gate 106, selection gate 108, LDD spacer 110 and/or source/drain region 112. Selection gate 108 may be formed by performing an etch-back process, for example slimming, after a spacer poly may be formed on and/or over a surface of a substrate by deposition. Salicidizing, deposition, masking, etching, and the like, may be selectively performed to selectively form salicide 114 at an upper part of memory gate 106 and/or selection gate 108. An interlayer insulating film, contact plugs and/or metal wires may be formed. A nonvolatile memory device may be manufactured on and/or over an active region defined by a device isolation film

A LDD spacer of a selection gate may be formed to minimize a bridge between a selection gate and a drain of a nonvolatile memory cell using a spacer poly for self-alignment. In a nonvolatile memory device, a spacer poly may be formed including a relatively large height (H) to minimize a bridge between a selection gate and a drain of a nonvolatile memory cell. Therefore, a memory gate may include a relatively large thickness. However, if memory gate 106 includes a relatively large thickness, as illustrated in example FIG. 2, photoresist (PR) 202 may include a relatively large thickness to prevent a poly from being damaged during etching. A photo margin may be minimized It may be relatively difficult to manufacture a nonvolatile memory device. Productivity may be minimized.

Accordingly, there is a need of a method of manufacturing a memory device, including a nonvolatile memory device, which may include a memory gate and/or a selection gate.

### SUMMARY

Embodiments relate to a method of manufacturing a nonvolatile memory. According to embodiments, a method of manufacturing a nonvolatile memory may include forming a spacer poly on and/or over a surface, which may be an entire surface, of a substrate including a memory gate. In embodiments, a method of manufacturing a nonvolatile memory may include forming a sacrificing material to etch-back a surface, which may be an entire surface, of a spacer poly. In embodiments, a method of manufacturing a nonvolatile memory may include removing a sacrificing material by etching, which may expose a surface of a spacer poly and/or which may form a sacrificing film to etch-back around a sidewall of a memory gate.

According to embodiments, a method of manufacturing a nonvolatile memory may include removing a spacer poly by etching, which may expose a part of a surface of a substrate and/or leave a spacer poly on and/or over a source forming region, which may be at a sidewall of a memory gate and/or under a sacrificing film. In embodiments, a method of manufacturing a nonvolatile memory may include removing a sacrificing film to form a selection gate at a side surface of a memory gate. In embodiments, a method of manufacturing a nonvolatile memory may include forming a source/drain region on and/or over a predetermined region of a substrate and/or forming metal wires which may be connected to a source/drain region through contact plugs.

According to embodiments, a spacer poly may be formed on and/or over a surface, which may be an entire surface, of a substrate including a memory gate. In embodiments, a sacrificing film, to etch back, may be formed on and/or over a surface of a spacer poly, and/or an etch-back process may be performed to form a selection gate. In embodiments, the thickness of a memory gate may be minimized In embodiments, a bridge between a selection gate, and/or a spacer poly gate, and a source/drain may be minimized.

### DRAWINGS

Example FIG. 1 is a sectional view of a nonvolatile memory device.

Example FIG. 2 is a sectional view of a memory cell manufactured by a manufacturing method in accordance with embodiments.

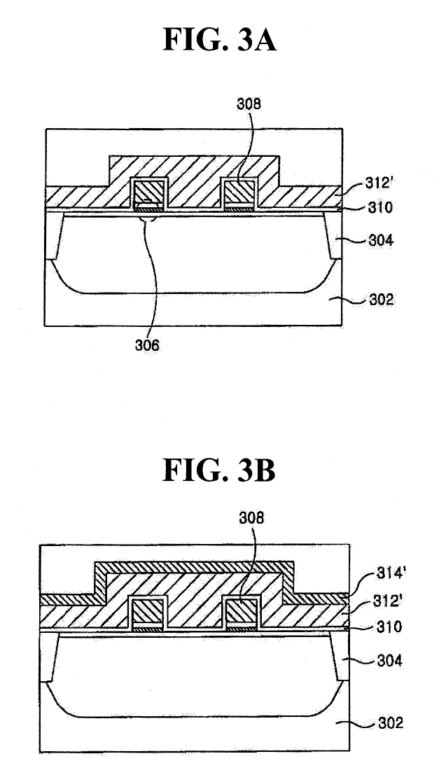

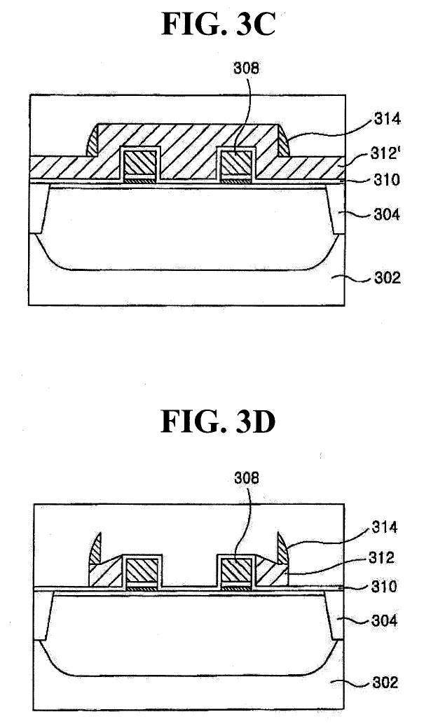

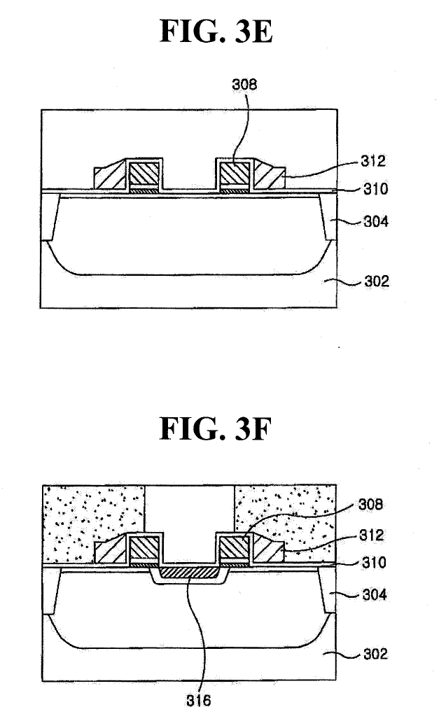

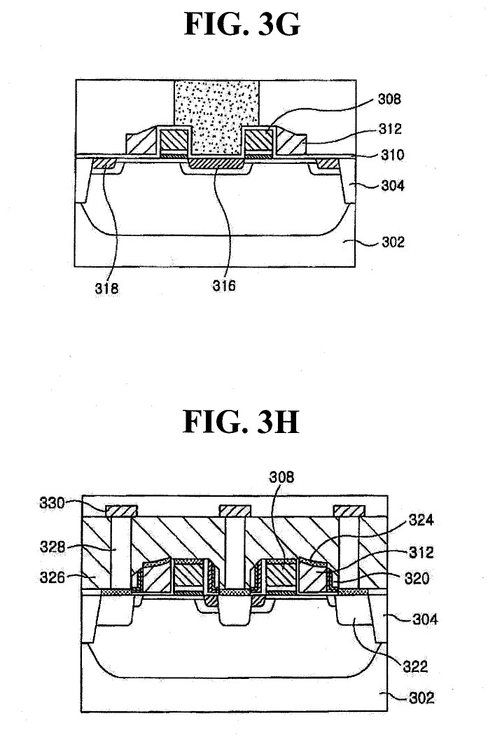

Example FIG. 3A to FIG. 3H are sectional views illustrating a method of manufacturing a nonvolatile memory device in accordance with embodiments.

### DESCRIPTION

Embodiments relate to a method of manufacturing a nonvolatile memory. Unlike when a spacer poly may be formed on and/or over a surface, which may be the entire surface, of a substrate including a memory gate such that an etch-back process may be performed to form a selection gate, embodiments relate to forming a spacer poly on and/or over a surface, which may be the entire surface, of a substrate having a memory gate and/or forming a sacrificing film to etch back on and/or over a surface, which may be the entire surface, of a spacer poly. In embodiments, an etch-back process may be performed to form a selection gate. In embodiments, a sacrificing film may be used in an etch-back process. In embodiments, a sacrificing film may include a chemical vapor deposition (CVD) oxide, a chemical vapor deposition (CVD) nitride, and the like.

Referring to example FIG. 3A to FIG. 3H, sectional views illustrate a method of manufacturing a nonvolatile memory device in accordance with embodiments. Referring to FIG. 3A, device isolation film 304, gate insulating film 306, memory gate 308 and/or buffer oxide film 310 may be formed on and/or over substrate 302. According to embodiments, gate insulating film may include a multilayer structure, for example oxide-nitride-oxide (ONO). In embodiments, deposition, for example chemical vapor deposition (CVD), may be performed to form spacer poly 312′ on and/or over a surface, which may be the entire surface, of substrate 302 including memory gate 308. In embodiments, spacer poly 312′ may be formed including a thickness between approximately 2000Å and 2500Å.

According to embodiments, deposition, for example CVD and the like, may be performed to form sacrificing material 314′ on and/or over a surface, which may be the entire surface, of the spacer poly 312′. In embodiments, sacrificing material 314′ may include a nitride and/or an oxide, and the like. In embodiments, sacrificing material 314′ may be formed including a thickness between approximately 200Å and 300Å.

Referring to FIG. 3C, an etch-back process, for example slimming, may be performed until a surface, for example an upper part, of spacer poly 312′ may be exposed. According to embodiments, sacrificing material 314′ may be removed. In embodiments, sacrificing film 314 may be formed at a sidewall of spacer poly 312′ corresponding to a sidewall of memory gate 308. In embodiments, a sacrificing material which may not be removed by an etch-back process may remain at a sidewall of spacer poly 312′ to form a sacrificing film.

Referring to FIG. 3D, an etch-back process may be performed until a surface of buffer oxide film 310 is exposed. According to embodiments, a portion of spacer poly 312′ may be removed. In embodiments, a portion of spacer poly 312′ covered by sacrificing film 314 may not be etched-back due to an etching selection ratio, for example between sacrificing film 314 and spacer poly 312′. In embodiments, a spacer poly on and/or over a source forming region, for example a region between two memory gates, at a sidewall of memory gate 308 and/or below sacrificing film 314 may remain after an etch-back process may be performed. In embodiments, the height of a poly at a portion where an LDD spacer may be formed may become the thickness at which the poly may be formed. In embodiments, a bridge between a spacer poly and a source/drain may be minimized In embodiments, a problem when the thickness of a memory gate increases to increase the height of a shoulder of a spacer poly may be resolved. Methods in accordance with embodiments may be applied in manufacturing all kinds of nonvolatile memory devices using a spacer poly. In embodiments, an existing logic gate thickness may be minimized In embodiments, a problem regarding consumption of a gate poly may be resolved.

Referring to FIG. 3E, a wet etching process may be performed to remove sacrificing film 314 which may have remained on and/or over spacer poly 312′. According to embodiments, selection gate 312 may be formed at a sidewall of the memory gate 308 including buffer oxide film 310 interposed therebetween. In embodiments, buffer oxide film 310 disposed under selection gate 312 may operate as a gate insulating film.

Referring to FIG. 3F, photoresist may be applied on and/or over a surface, which may be the entire surface, of substrate 302. According to embodiments, exposure and/or development may be performed to form an etching mask through which source forming region may be selectively exposed. In embodiments, etching may be performed until a surface of buffer oxide film 310 may be exposed. In embodiments, a spacer poly on and/or over a source forming region may be completely removed. In embodiments, source ion implantation may be performed to form source ion implanted layer 316.

Referring to FIG. 3G, photoresist may be applied on and/or over a surface, which may be an entire surface, of substrate 302. According to embodiments, exposure and/or development may be performed to form an etching mask through which a drain forming region may be selectively exposed. In embodiments, drain ion implantation may be performed to form drain ion implanted layer 318. In embodiments, drain ion implanted layer 318 may be formed simultaneously with a drain region of a logic device.

Referring to FIG. 3H, deposition may be performed to form a spacer material, for example silicon nitride and the like, on and/or over a surface, which may be the entire surface, of substrate 302. According to embodiments, an etch-back process may be performed to form LDD spacer 320 at sidewalls of memory gate 308 and/or selection gate 312. In embodiments, high-concentration, ion implantation may be performed using memory gate 308, selection gate 312 and/or LDD spacer 320 as an ion implantation mask to form source/drain region 322.

According to embodiments, deposition may be performed to form a metal material, for example, Ti, TiN, Co, Ni, Pt, and/or W, and the like, to form a salicide on and/or over a surface, which may be an entire surface, of substrate 302. In embodiments, heat treatment may be performed under a predetermined process condition to cause a reaction between an underlying film and a metal material. In embodiments, a metal material formed on and/or over memory gate 308, selection gate 312 and/or source/drain region 322 may be salicidized, and/or a metal material on and/or over a region other than a salicidized portion may be selectively removed. In embodiments, salicide 324 may be formed on and/or over memory gate 308, selection gate 312 and/or source/drain region 322. In embodiments, high-concentration ion implantation and/or salicidizing to form source/drain region 322 may be performed simultaneously with high-concentration ion implantation and/or salicidizing of a logic device.

According to embodiments, deposition may be performed to form an insulating material, such as tetraethyl orthosilicate (TEOS) and the like, at a predetermined thickness on and/or over a surface, which may be the entire surface, of substrate 302. In embodiments, planarization, such as chemical mechanical polishing (CMP), and the like, may be performed. In embodiments, thick interlayer insulating film 326 may be formed to completely cover memory gate 308 and/or the selection gate 312.

According to embodiments, photoresist may be applied on and/or over interlayer insulating film 326. In embodiments, exposure and/or development may be performed to form an etching mask through which contact plug forming regions may be selectively exposed. In embodiments, etching may be performed until a surface of salicide 324 formed on and/or over source/drain region 322 may be exposed, such that a contact hole may formed. In embodiments, deposition, such as sputtering and the like, may be performed to fill a metal material on and/or over contact hole. In embodiments, contact plugs 328 which may be connected to source/drain region 322 may be formed. In embodiments, deposition, such as sputtering and the like, and/or etching using an etching mask may be performed to form metal wires 330 on and/or over contact plugs 328.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a spacer poly over a surface of a substrate comprising a memory gate;
forming a sacrificing material over a surface of said spacer poly;
removing said sacrificing material by etching to expose a surface of said spacer poly and to form a sacrificing film to etch-back around a sidewall of said memory gate;
removing said spacer poly by etching such that a surface of the substrate is exposed and such that a portion of said spacer poly remain over a source forming region at a sidewall of said memory gate below said sacrificing film;
removing said sacrificing film to form a selection gate at a side surface of said memory gate;
forming a source/drain region over a predetermined region of the substrate; and
forming metal wires connected with said source/drain region through contact plugs.

2. The method of claim 1, wherein the thickness of said spacer poly is between approximately 2000Å and 2500Å.

3. The method of claim 1, wherein said sacrificing material comprises at least one of a nitride and an oxide.

4. The method of claim 3, wherein forming said sacrificing material comprises chemical vapor deposition.

5. The method of claim 3, wherein the thickness of said sacrificing material is between approximately 200Å and 300Å.

6. The method of claim 1, wherein removing said sacrificing material comprises an etch-back process.

7. The method of claim 1, wherein removing said spacer poly comprises an etch-back process.

8. The method of claim 1, wherein removing said sacrificing film comprises wet etching.

9. The method of claim 1, wherein forming said source/drain region comprises:
removing said spacer poly formed over said source forming region and performing ion implantation to form a source ion implanted layer;
selectively exposing a drain forming region and performing ion implantation to form a drain ion implanted layer;
forming a lightly doped drain spacer at a sidewall of said memory gate and said selection gate; and
implanting high-concentration ions over said source ion implanted region and said drain ion implanted layers to form said source/drain region.

10. The method of claim 9, comprising:
forming salicide over at least one of said memory gate, said selection gate and said source/drain region;
forming an interlayer insulating film over a surface of the substrate;
selectively removing a portion of said interlayer insulating film to form contact plugs; and
forming metal wires connected said source/drain region.

11. The method of claim 10, wherein implanting said high-concentration ions and forming said salicide are performed simultaneously with high-concentration ion implantation and salicide formation of a logic device.

12. The method of claim 9, wherein said drain ion implanted layer is formed simultaneously with a drain region of a logic device.

13. An apparatus comprising:
a memory gate;
a selection gate at a sidewall of said memory gate and spaced apart from said memory gate by a buffer oxide film;
a lightly doped drain spacer at said sidewall of said memory gate and said selection gate;
a source/drain region;
salicide over at least one of said memory gate, said selection gate and said source/drain region;
an interlayer insulating film over a surface of the substrate; and
contact plugs and metal wires connected to said source/drain region.

14. The apparatus of claim 13, wherein said source/drain region comprise high-concentration ions implanted over a source ion implanted layer and a drain ion implanted layer.

15. The apparatus of claim 14, wherein said drain ion implanted layer is formed simultaneously with a drain region of a logic device.

16. The apparatus of claim 13, wherein implanting said high-concentration ions and forming salicide are performed simultaneously with high-concentration ion implantation and salicide formation of a logic device.

17. The apparatus of claim 13, comprising a nonvolatile memory device

18. The apparatus of claim 13, wherein said buffer oxide film is disposed between said substrate and said selection gate.

19. The apparatus of claim 13, comprising a plurality of at least one of said memory gate and said selection gate.

20. The apparatus of claim 19, where said plurality is disposed between a device isolation film.
